(19) United States
(12) Patent Application Publication
(10) Pub. No.: US 2025/0005888 A1
(43) Pub. Date: Jan. 2, 2025

(54) Image Processing Method, Electronic Device, and Storage Medium

(71) Applicant: TENCENT TECHNOLOGY (SHENZHEN) COMPANY LIMITED, Shenzhen (CN)

(72) Inventors: Ruifen ZHANG, Shenzhen (CN); Luyan LIU, Shenzhen (CN); Hong WANG, Shenzhen (CN); Yawen HUANG, Shenzhen (CN); Yefeng ZHENG, Shenzhen (CN)

(21) Appl. No.: 18/808,070

(22) Filed: Aug. 18, 2024

Related U.S. Application Data
(63) Continuation of application No. PCT/CN2023/095109, filed on May 18, 2023.

(30) Foreign Application Priority Data
Jul. 25, 2022 (CN) 202210876986.3

(51) Int. Cl. G06V 10/42; G06T 5/10; G06V 10/771

(52) U.S. Cl. CPC G06V 10/431; G06T 5/10; G06V 10/771

(57) ABSTRACT

An image processing method includes: obtaining, through a plurality of radio frequency coils, a plurality of pieces of corresponding undersampled frequency-domain data respectively; and performing, by using a plurality of image processing networks that are cascaded, an information supplement operation respectively on the plurality of pieces of frequency-domain data to obtain a plurality of corresponding target restored images, and determining a target reconstructed image based on the plurality of target restored images, a piece of frequency-domain data being configured for obtaining one target restored image, and an image processing network including an image restoring network, a frequency-domain complement network, and a susceptibility estimation network.

### CROSS-REFERENCES TO RELATED APPLICATIONS

This application is a continuation application of PCT Patent Application No. PCT/CN2023/095109, filed on May 18, 2023, which claims priority to Chinese Patent Application No. 202210876986.3 filed on Jul. 25, 2022, all of which is incorporated by reference in their entirety.

### FIELD OF THE TECHNOLOGY

The present disclosure relates to the field of artificial intelligence technologies and, in particular, to an image processing method and apparatus, an electronic device, a storage medium, and a program product.

### BACKGROUND OF THE DISCLOSURE

With the development of medical technologies and the popularization of medical image capturing, medical images are now commonly used to learn the health status of a patient. The magnetic resonance imaging (MRI) technology can provide high-quality reference information through high-resolution and high-contrast images. However, the MRI requires longer scanning time than other medical imaging technologies. Long scanning time may cause patient discomfort and may alternatively generate motion artifacts that affect the quality of MRI images.

In related art, undersampled K-space data is collected by a radio frequency coil according to a sampling mask, and then magnetic resonance imaging is reconstructed based on the undersampled K-space data. However, information may be missed in the undersampled K-space data, resulting in poor quality of MRI images reconstructed based on the undersampled K-space data.

### SUMMARY

One embodiment of the present disclosure provides an image processing method performed by an electronic device. The method includes: obtaining, through a plurality of radio frequency coils, a plurality of pieces of undersampled frequency-domain data respectively, a radio frequency coil being configured to obtain one piece of undersampled frequency-domain data; performing, by using a plurality of image processing networks that are cascaded, an information supplement operation respectively on the plurality of pieces of frequency-domain data to obtain a plurality of corresponding target restored images, a piece of frequency-domain data being configured for obtaining one target restored image, and an image processing network comprising an image restoring network, a frequency-domain complement network, and a susceptibility estimation network; and determining a target reconstructed image based on the plurality of target restored images.

Another embodiment of the present disclosure provides a computer device, including a memory, at least one processor, and a computer program stored in the memory and executable on the at least one processor for performing: obtaining, through a plurality of radio frequency coils, a plurality of pieces of undersampled frequency-domain data respectively, a radio frequency coil being configured to obtain one piece of undersampled frequency-domain data; performing, by using a plurality of image processing networks that are cascaded, an information supplement operation respectively on the plurality of pieces of frequency-domain data to obtain a plurality of corresponding target restored images, a piece of frequency-domain data being configured for obtaining one target restored image, and an image processing network comprising an image restoring network, a frequency-domain complement network, and a susceptibility estimation network; and determining a target reconstructed image based on the plurality of target restored images

Another embodiment of the present disclosure provides a non-transitory computer-readable storage medium containing a computer program that, when being executed, causes a computer device to perform: obtaining, through a plurality of radio frequency coils, a plurality of pieces of undersampled frequency-domain data respectively, a radio frequency coil being configured to obtain one piece of undersampled frequency-domain data; performing, by using a plurality of image processing networks that are cascaded, an information supplement operation respectively on the plurality of pieces of frequency-domain data to obtain a plurality of corresponding target restored images, a piece of frequency-domain data being configured for obtaining one target restored image, and an image processing network comprising an image restoring network, a frequency-domain complement network, and a susceptibility estimation network; and determining a target reconstructed image based on the plurality of target restored images.

### BRIEF DESCRIPTION OF THE DRAWINGS

To describe the technical solutions of embodiments of the present disclosure more clearly, the following briefly describes the accompanying drawings required for describing embodiments. Apparently, the accompanying drawings in the following description show only some embodiments of the present disclosure, and a person of ordinary skill in the art may still derive other drawings from these accompanying drawings without creative efforts.

FIG. 1 is a schematic diagram of a structure of a system architecture according to an embodiment of the present disclosure.

FIG. 2 is a schematic flowchart of an image processing method according to an embodiment of the present disclosure.

FIG. 3 is a schematic diagram of a network structure according to an embodiment of the present disclosure.

FIG. 4 is a schematic diagram of a network structure according to an embodiment of the present disclosure.

FIG. 5 is a schematic diagram of a network structure according to an embodiment of the present disclosure.

FIG. 6 is a schematic diagram of a network structure according to an embodiment of the present disclosure.

FIG. 7 is a schematic diagram of a network structure according to an embodiment of the present disclosure.

FIG. 8 is a schematic diagram of a network structure according to an embodiment of the present disclosure.

FIG. 9 is a schematic diagram of a network structure according to an embodiment of the present disclosure.

FIG. 10A is a schematic flowchart of an image processing method according to an embodiment of the present disclosure.

FIG. 10B is a schematic diagram of a structure of an image processing apparatus according to an embodiment of the present disclosure.

FIG. 11 is a schematic diagram of a structure of a computer device according to an embodiment of the present disclosure.

### DESCRIPTION OF EMBODIMENTS

To make the objectives, technical solutions, and beneficial effects of the present disclosure clearer, the following further describes the present disclosure in detail with reference to the accompanying drawings and embodiments. The specific embodiments described herein are merely used to explain the present disclosure but are not intended to limit the present disclosure.

For ease of understanding, terms in embodiments of the present disclosure are explained below.

Artificial intelligence (AI) is a theory, method, technology, and application system that use a digital computer or a machine controlled by the digital computer to simulate, extend, and expand human intelligence, perceive an environment, acquire knowledge, and use knowledge to obtain an optimal result. In other words, the artificial intelligence is a comprehensive technology in computer science and attempts to understand the essence of intelligence and produce a new intelligent machine that can react in a manner similar to human intelligence. The artificial intelligence is to study the design principles and implementation methods of various intelligent machines, to enable the machines to have the functions of perception, reasoning, and decision-making.

The artificial intelligence technology is a comprehensive discipline, and relates to a wide range of fields including both hardware-level technologies and software-level technologies. The basic artificial intelligence technologies generally include technologies such as a sensor, a dedicated artificial intelligence chip, cloud computing, distributed storage, a big data processing technology, an operating/interaction system, and electromechanical integration. Artificial intelligence software technologies mainly include several major directions such as a computer vision technology, a speech processing technology, a natural language processing technology, and machine learning/deep learning.

Machine learning (ML) is a multi-field interdiscipline, and relates to a plurality of disciplines such as the probability theory, statistics, the approximation theory, convex analysis, and the algorithm complexity theory. The machine learning specializes in studying how a computer simulates or implements a human learning behavior to obtain new knowledge or skills, and reorganize an existing knowledge structure, so as to keep improving its performance. The machine learning is the core of artificial intelligence, is a basic way to make the computer intelligent, and is applied to various fields of the artificial intelligence. The machine learning and deep learning generally include technologies such as an artificial neural network, a belief network, reinforcement learning, transfer learning, inductive learning, and learning from demonstrations. For example, in embodiments of the present disclosure, a magnetic resonance imaging (MRI) image is reconstructed by using the machine learning technology.

Magnetic resonance imaging: It is a medical imaging technology in which detailed images of organs and tissues within a body of an animal (such as a human being) are created by using radio waves generated by magnetic field and computers.

K-space: It is an extension of a Fourier space concept in MRI imaging. The K-space represents space frequency information in two dimensions or three dimensions of an object, and is defined by space covered by a phase and frequency encoding data.

K-space data: It is obtained by transforming an image from an image domain (that is, a time domain) to a frequency domain (K-space domain), and is a two-dimensional Fourier transform result of image data of the image domain. A number of data points in the K-space data is same as a number of pixel points restored by performing an inverse Fourier transform according to the K-space data. Each data point is a complex number, and is configured for describing an amplitude and a phase of a pixel point. An included angle between a real part and an imaginary part of the complex number is the phase, and a root of a sum of squares of the real part and the imaginary part is the amplitude. The inverse Fourier transform can be performed on the K-space data to restore the image. For example, when there are 1,024 data points in the K-space data, an image with a resolution of 32×32 (1024=32×32) can be restored. When there are 4,096 data points in the K-space, an image with a resolution of 64×64 (4096=64×64) can be restored.

A plurality of radio frequency coils: In multi-channel nuclear magnetic resonance imaging, each radio frequency coil obtains undersampled K-space data of a corresponding body part under guidance of a sampling mask. Because the undersampled K-space data is only partially sampled, scanning time is shortened. An MRI image is reconstructed from the undersampled K-space data collected respectively by all radio frequency coils.

Oversampling: It has a sampling frequency twice higher than the highest frequency of an electromagnetic wave signal emitted by a radio frequency coil, and this type of sampling is referred to as the oversampling.

Undersampling: It has a sampling frequency twice lower than the highest frequency of an electromagnetic wave signal emitted by a radio frequency coil, and this type of sampling is referred to as the undersampling.

Full sampling: It has a sampling frequency twice the highest frequency of an electromagnetic wave signal emitted by a radio frequency coil, and this type of sampling is referred to as the full sampling.

In a process of implementing embodiments of the present disclosure, it is found by the applicant that in related art, to save MRI scanning time, undersampled K-space data is collected concurrently by using a plurality of radio frequency coils according to a sampling mask, and then magnetic resonance imaging is reconstructed based on the undersampled K-space data. However, information may be missed in the undersampled K-space data, resulting in poor quality of MRI images reconstructed based on the undersampled K-space data.

It is found by the applicant through analysis that coil susceptibility can be used as supplementary information for information supplement on the undersampled K-space data. In addition, a deep learning method shows excellent performance in inverse problems of imaging such as denoising, compressed sensing, and super-resolution. Therefore, if the deep learning is used, multi-level information compensation is performed on the undersampled K-space data based on the coil susceptibility to obtain complementary K-space data. Then, a reconstructed MRI image is obtained based on the complementary K-space data, and the quality of the MRI image is effectively improved.

In view of this, embodiments of the present disclosure provide an image processing method, including: obtaining, by a plurality of radio frequency coils, a plurality of pieces of corresponding undersampled frequency-domain data respectively; and performing, by using a plurality of image processing networks that are cascaded, an information supplement operation respectively on the plurality of pieces of obtained frequency-domain data to obtain a plurality of corresponding target restored images, and determining a target reconstructed image based on the plurality of obtained target restored images, each radio frequency coil being configured to obtain one piece of undersampled frequency-domain data, and each image processing network including an image restoring network, a frequency-domain complement network, a susceptibility estimation network.

The performing, by using a plurality of image processing networks that are cascaded, an information supplement operation respectively on the plurality of pieces of frequency-domain data to obtain a plurality of corresponding target restored images may be implemented in the following manners: performing, for each frequency-domain data, the following operations in sequence according to a cascading order of the plurality of image processing networks: performing, for the first image processing network by an image restoring network in a current cascade, image-domain information supplement on the frequency-domain data, and inputting an obtained restored image in the current cascade to a frequency-domain complement network in a next cascade for frequency-domain information supplement; and performing, by a frequency-domain complement network in the current cascade, frequency-domain information supplement on the frequency-domain data, and inputting obtained frequency-domain complement data in the current cascade to a susceptibility estimation network in the next cascade for susceptibility supplement; and performing, for each non-first image processing network by an image restoring network in a current cascade, image-domain information supplement on frequency-domain complement data output by a frequency-domain complement network in a previous cascade and coil susceptibility output by a susceptibility estimation network in the previous cascade to obtain a restored image in the current cascade, and using the restored image in the current cascade output by an image processing network in the last cascade as the target reconstructed image.

In embodiments of the present disclosure, an information supplement operation is performed respectively on a plurality of pieces of obtained undersampled frequency-domain data by using a plurality of image processing networks that are cascaded to obtain corresponding target restored images, and a target reconstructed image is determined based on the plurality of obtained target restored images. In a process of obtaining the target restored images, an image restoring network, a frequency-domain complement network, and a susceptibility estimation network in the plurality of image processing networks perform cross information supplement in dimensions of an image domain, a frequency domain, and susceptibility information, to obtain more comprehensive image information. In this way, quality of the target reconstructed image is effectively improved when image reconstruction is performed based on the more comprehensive image information that is obtained.

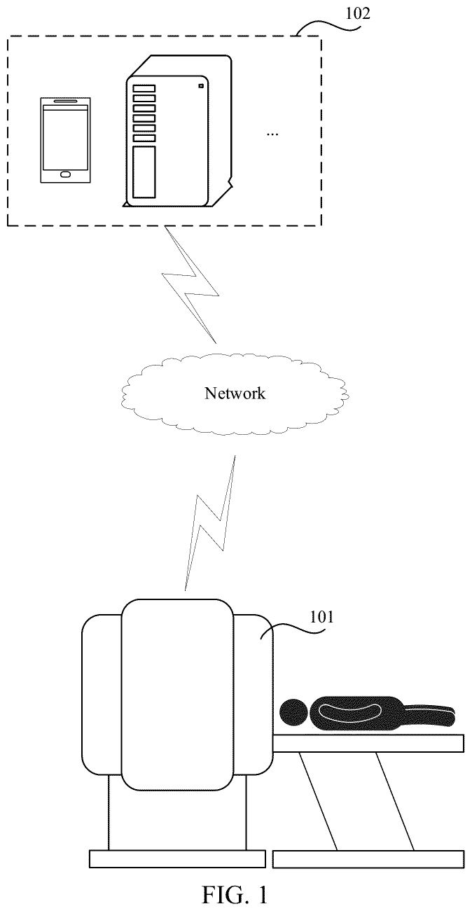

FIG. 1 is a diagram of a system architecture of an MRI system applicable to an embodiment of the present disclosure. The system architecture includes at least a signal collecting device 101 and an image reconstructing device 102.

The signal collecting device 101 includes a plurality of radio frequency (RF) coils. Each RF coil emits a RF signal to a human being or an animal, and receives an MR signal emitted from the human or the animal. Specifically, to induce an atomic nucleus to transfer from a low-energy state to a high-energy state, the RF coil generates an electromagnetic wave signal and applies the electromagnetic wave signal to a patient. The electromagnetic wave signal is a RF signal corresponding to a type of the atomic nucleus. When the electromagnetic wave signal generated by the RF coil is applied to the atomic nucleus, the atomic nucleus may transfer from the low-energy state to the high-energy state. Then, when the RF coil no longer generates an electromagnetic wave signal, the atomic nucleus that is in the body of the patient and that is previously applied the electromagnetic wave signal transfers from the high-energy state to the low-energy state, so that an electromagnetic wave signal having Larmor frequency is emitted, and the RF coil receives the electromagnetic wave signal released form the atomic nucleus of the body of the patient.

When the electromagnetic wave signal is received, the RF coil sends a RF signal sequence of part of discrete phases according to a sampling mask, to obtain undersampled K-space data, and sends the undersampled K-space data to the image reconstructing device 102.

The image reconstructing device 102 performs an information supplement operation respectively on a plurality of pieces of obtained undersampled K-space data by using a plurality of image processing networks that are cascaded to obtain a plurality of corresponding target restored images, and determine a target reconstructed image based on the plurality of obtained target restored images.

The foregoing image reconstructing device 102 may be a terminal device or a server. The terminal device may be a smart phone, a tablet computer, a notebook computer, a desktop computer, an intelligent voice interaction device, an intelligent vehicle-mounted device, and the like. The server may be an independent physical server, a server cluster or a distributed system including a plurality of physical servers, or a cloud server that provides a basic cloud computing service such as a cloud service, a cloud database, cloud computing, a cloud function, cloud storage, a network service, cloud communication, a middleware service, a domain name service, a security service, a content delivery network (CDN), and a big data and artificial intelligence platform. The signal collecting device 101 may be directly or indirectly connected to the image reconstructing device 102 via wired or wireless communications, which is not limited in embodiments of the present disclosure.

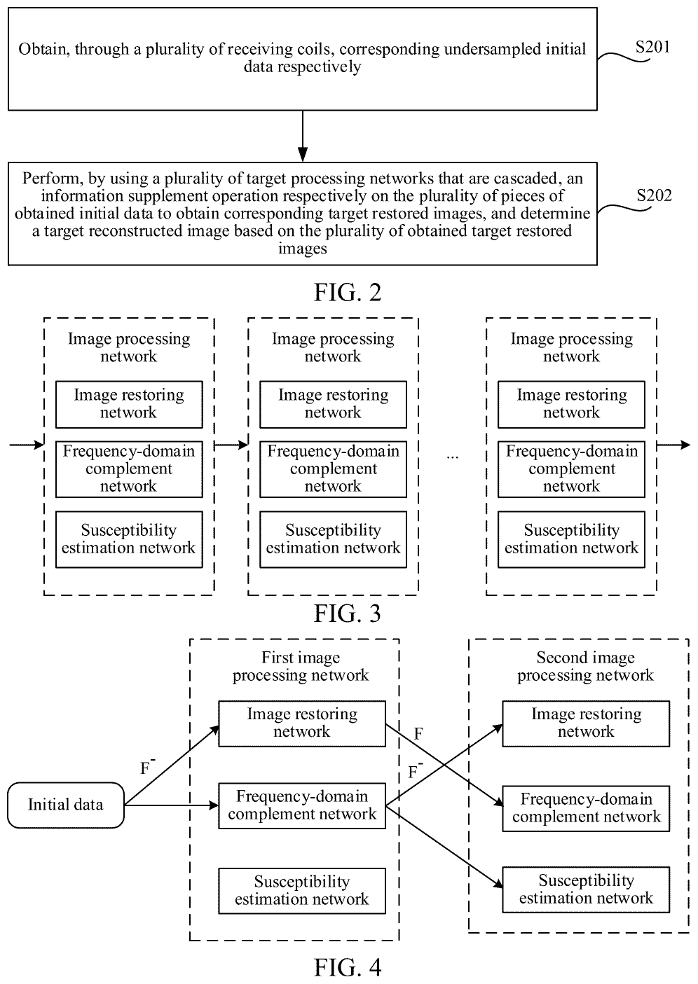

Based on the diagram of the system architecture shown in FIG. 1, an embodiment of the present disclosure provides a process of an image processing method, as shown in FIG. 2. The process of the method is performed by a computer device. The computer device may be the image reconstructing device 102 shown in FIG. 1. The method includes the following operations:

Step S201: Obtain, by a plurality of radio frequency coils, a plurality of pieces of undersampled frequency-domain data respectively.

Each radio frequency coil is configured to obtain one piece of undersampled frequency-domain data. Specifically, the following processing is performed by each radio frequency coil: directly collecting, by the radio frequency coil, undersampled K-space data to be used as a piece of undersampled frequency-domain data; or collecting fully-sampled K-space data by the radio frequency coil, performing undersampling processing by adding a mask in the fully-sampled K-space data, and using the obtained undersampled K-space data as a piece of undersampled frequency-domain data.

Step S202: Perform, by using a plurality of image processing networks that are cascaded, an information supplement operation respectively on the plurality of pieces of obtained frequency-domain data to obtain a plurality of corresponding target restored images, and determine a target reconstructed image based on the plurality of obtained target restored images.

Each piece of frequency-domain data includes undersampled K-space data obtained when a radio frequency coil performs scanning once on a human being or an animal. One piece of frequency-domain data includes a plurality of data points that may be configured for reconstructing a two-dimensional image of a scanned part of the human being or the animal, that is, the target restored image. The plurality of target restored images are configured for synthesizing a three-dimensional image of the scanned part, that is, the target reconstructed image. Various solutions provided in related art may be used to perform synthesis from two dimensions to three dimensions, for example, a surface rendering technology.

Specifically, a network structure formed by the plurality of image processing networks is shown in FIG. 3. Each image processing network includes an image restoring network, a frequency-domain complement network, and a susceptibility estimation network. The undersampled K-space data, the restored image, and coil susceptibility are in a form of complex numbers. Each of input layers of the image restoring network, the frequency-domain complement network, and the susceptibility estimation network is provided with two input channels, which are an imaginary part input channel and a real part input channel. The image restoring network, the frequency-domain complement network, and the susceptibility estimation network may be a fully convolutional network such as a U-Net, or may be a network in another form, which is not limited in embodiments of the present disclosure. In addition, the foregoing step S201 and step S202 are a process of processing frequency-domain data obtained by a group (slice) of radio frequency coils to obtain a target reconstructed image. The foregoing step S201 and step S202 are repeatedly performed to process frequency-domain data obtained by another group (slice) of radio frequency coils to obtain a target reconstructed image corresponding to the another group of radio frequency coils. Then, a three-dimensional MRI image is obtained based on a target reconstructed image corresponding to the plurality of radio frequency coils.

A process of the first image processing network processing frequency-domain data is described below with reference to the network structure shown in FIG. 3, as shown in FIG. 4.

For the first image processing network, image-domain information supplement is performed on undersampled frequency-domain data (that is, undersampled K-space data, which is referred to as frequency-domain data below) by an image restoring network in a current cascade, and an obtained restored image in the current cascade is input to a frequency-domain complement network in a next cascade for frequency-domain information supplement. Then, frequency-domain information supplement is performed on the frequency-domain data by a frequency-domain complement network in the current cascade, and obtained frequency-domain complement data in the current cascade is input to a susceptibility estimation network in the next cascade for susceptibility supplement.

Specifically, an inverse Fourier transform (F⁻) is performed on the frequency-domain data to obtain an initial time-domain image. Then, image-domain information supplement is performed on the initial time-domain image by the image restoring network in the first image processing network to obtain the restored image in the current cascade. A Fourier transform (F) is performed on the restored image in the current cascade to obtain frequency-domain data corresponding to the restored image, and the frequency-domain data corresponding to the restored image is input to the frequency-domain complement network in the next cascade (a frequency-domain complement network in the second image processing network) for frequency-domain information supplement.

The undersampled frequency-domain data is the undersampled K-space data. Therefore, the frequency-domain data may be directly input to the frequency-domain complement network in the first image processing network for the frequency-domain information supplement to obtain the frequency-domain complement data in the current cascade. The frequency-domain complement data in the current cascade is input to the susceptibility estimation network in the next cascade (a susceptibility estimation network in the second image processing network) for the susceptibility supplement. In addition, after the inverse Fourier transform is performed on the frequency-domain complement data in the current cascade, a time-domain image corresponding to the frequency-domain complement data is obtained, and the time-domain image corresponding to the frequency-domain complement data is input to an image restoring network in the next cascade (that is, an image restoring network in the second image processing network) for the image-domain information supplement.

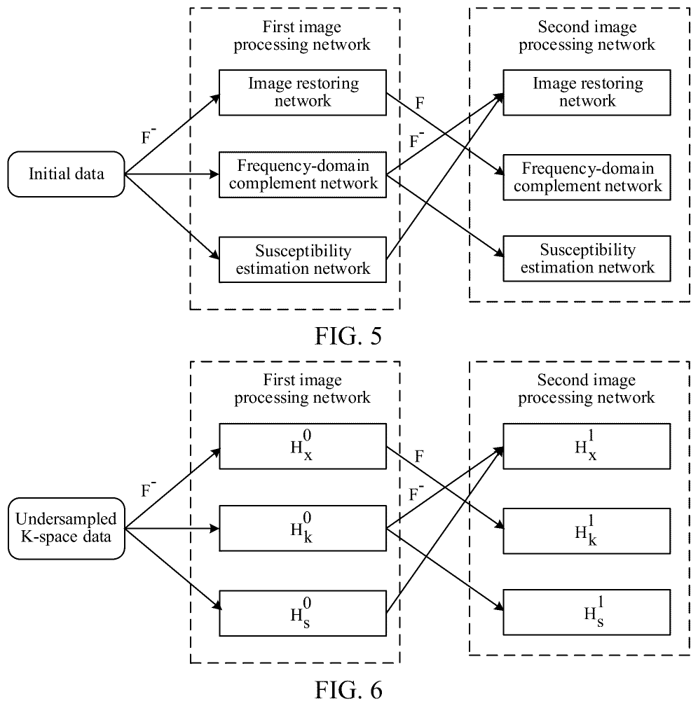

In some embodiments, as shown in FIG. 5, for the first image processing network, target data within a preset frequency range is selected from the frequency-domain data, and an inverse Fourier transform (F⁻) is performed on the target data to obtain initial coil susceptibility. Susceptibility supplement is performed on the initial coil susceptibility by a susceptibility estimation network in the current cascade, and obtained coil susceptibility in the current cascade is input to the frequency-domain complement network in the next cascade for frequency-domain information supplement.

Specifically, data lower than the preset frequency is selected from the undersampled K-space data to be used as the target data. Then, the inverse Fourier transform is performed on the target data to obtain a time-domain image corresponding to the target data to be used as the initial coil susceptibility in a form of images. In addition, the susceptibility supplement is performed on the initial coil susceptibility by the susceptibility estimation network in the first image processing network to obtain coil susceptibility in the current cascade in a form of images. The coil susceptibility is input to the frequency-domain complement network in the next cascade (that is, the frequency-domain complement network in the second image processing network) for the frequency-domain information supplement.

For example, as shown in FIG. 6, the first image processing network includes an image restoring network Hₓ⁰, a frequency-domain complement network Hₖ⁰, and a susceptibility estimation network Hₛ⁰. The second image processing network includes an image restoring network Hₓ¹, a frequency-domain complement network Hₖ¹, and a susceptibility estimation network Hₛ¹.

An inverse Fourier transform (F⁻) is performed on undersampled K-space data to obtain a time-domain image corresponding to the undersampled K-space data. Zero is filled in the time-domain image corresponding to the undersampled K-space data (for example, 0 is filled around a 32×32 time-domain image to obtain a 40×40 zero-filled image) to obtain a zero-filled image (that is, an initial time-domain image). Frequency-domain data corresponding to the zero-fill image is smoother than frequency-domain data corresponding to the time-domain image before zero filling. Then, image-domain information supplement is performed on the zero-filled image by the image restoring network Hₓ⁰ to obtain a restored image in a current cascade. A Fourier transform is performed on the restored image in the current cascade to obtain frequency-domain data corresponding to the restored image, and the frequency-domain data corresponding to the restored image is input to the frequency-domain complement network Hₖ¹ in the second image processing network.

The undersampled K-space data is input to the frequency-domain complement network Hₖ⁰ to obtain frequency-domain complement data in the current cascade. The frequency-domain complement data in the current cascade is input to the susceptibility estimation network Hₛ¹, in the second image processing network, and an inverse Fourier transform (F⁻) is performed on the frequency-domain complement data in the current cascade, then the frequency-domain complement data in the current cascade is input to the image restoring network Hₓ¹ in the second image processing network.

Target frequency-domain data lower than a preset frequency is selected from the undersampled K-space data. Then, an inverse Fourier transform (F⁻) is performed on the target frequency-domain data to obtain a time-domain image corresponding to the target frequency-domain data, and the time-domain image corresponding to the target frequency-domain data is used as initial coil susceptibility in a form of images. In addition, susceptibility supplement is performed on the initial coil susceptibility by the susceptibility estimation network Hₛ⁰ in the first image processing network to obtain coil susceptibility in the current cascade in a form of images. The coil susceptibility in the current cascade is input to the image restoring network Hₓ¹ in the second image processing network.

In embodiments of the present disclosure, frequency-domain information supplement is performed on undersampled K-space data by using a frequency-domain complement network, image-domain information supplement is performed on the undersampled K-space data by using an image restoring network, and coil susceptibility supplement is performed on the undersampled K-space data by using a susceptibility estimation network, to implement information supplement on multi-dimensions of a frequency domain and an image domain, so as to obtain more complete K-space data. In this way, quality of a reconstructed image can be effectively improved when image reconstruction is performed based on the complete K-space data.

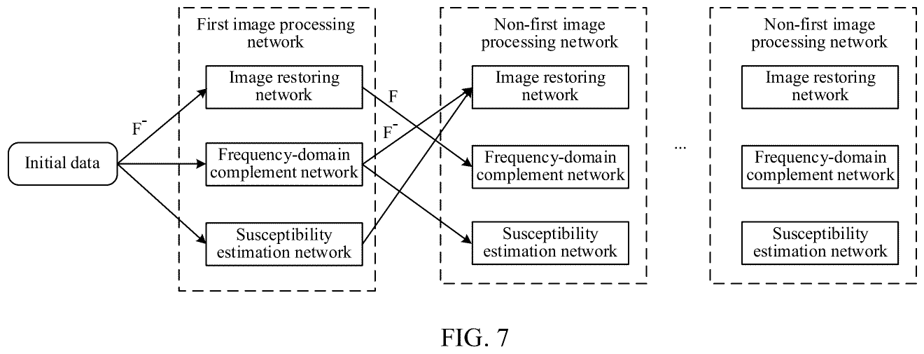

A process of a non-first image processing network processing frequency-domain data with reference to the network structure shown in FIG. 3, as shown in FIG. 7, which includes the following operations:

performing, by an image restoring network in a current cascade, image-domain information supplement on frequency-domain complement data output by a frequency-domain complement network in a previous cascade and coil susceptibility output a susceptibility estimation network in the previous cascade to obtain a restored image in the current cascade; performing, by a frequency-domain complement network in the current cascade, frequency-domain information supplement on a restored image output by an image restoring network in the previous cascade to obtain frequency-domain complement data in the current cascade; and performing, by a susceptibility estimation network in the current cascade, susceptibility supplement on the frequency-domain complement data output by the frequency-domain complement network in the previous cascade to obtain coil susceptibility in the current cascade.

Specifically, an inverse Fourier transform and a shrinking operation are performed on the frequency-domain complement data output by the frequency-domain complement network in the previous cascade to obtain a time-domain image. For example, an inverse Fourier transform is performed on the frequency-domain complement data (that is, the frequency-domain complement data output by the frequency-domain complement network in the previous cascade) to obtain a time-domain image corresponding to the frequency-domain complement data, and a shrinking operation is performed on the time-domain image corresponding to the frequency-domain complement data to obtain a time-domain image after the shrinking operation.

Then, the image-domain information supplement is performed, by the image restoring network in the current cascade, on the time-domain image after the shrinking operation and the coil susceptibility output by the susceptibility estimation network in the previous cascade to obtain the restored image in the current cascade. If the image restoring network in the current cascade is the last image processing network, the restored image in the current cascade is used as a target restored image for a reconstructed image. If the image restoring network in the current cascade is not located in the last image processing network, a Fourier transformed (F) is performed on the restored image in the current cascade, and then restored image in the current cascade is input to a frequency-domain complement network in a next image processing network for the frequency-domain information supplement.

A formula of the shrinking operation R is as follows:

$$R ( {x}_{1} , … , {x}_{N} ) = {\sum }_{i} {S}_{i}^{*} {x}_{i} … … … … \qquad ( 1 )$$

x₁, . . . , x_{N} are the time-domain images obtained by performing the inverse Fourier transform on the frequency-domain complement data. Sᵢ is susceptibility of an i^{th} radio frequency coil. St is a conjugate complex number of Sᵢ.

A Fourier transform and an extended operation are performed on the restored image output by the image restoring network in the previous cascade to obtain corresponding to-be-complemented frequency-domain data. For example, a Fourier transform is performed on the restored image (that is, the restored image output by the image restoring network in the previous cascade) to obtain frequency-domain data corresponding to the restored image, and an extended operation is performed on the frequency-domain data corresponding to the restored image to obtain frequency-domain data after the extended operation. Then, frequency-domain information supplement is performed, by the frequency-domain complement network in the current cascade, on the to-be-complemented frequency-domain data (the frequency-domain data after the extended operation output by the image restoring network in the previous cascade) to obtain the frequency-domain complement data in the current cascade. If the frequency-domain complement network in the current cascade is not the last image processing network, the frequency-domain complement data in the current cascade is input to a susceptibility estimation network of a next image processing network for susceptibility supplement, and an inverse Fourier transform (F⁻) is performed on the frequency-domain complement data in the current cascade, then the frequency-domain complement data in the current cascade is input to an image restoring network in the next image processing network for image-domain information supplement.

A formula of the extended operation E is as follows:

$$ℰ ( x ) = ( {S}_{1} x , … , {S}_{N} x ) \qquad ( 2 )$$

S₁, . . . , S_{N} is susceptibility of the first radio frequency coil to an Nth radio frequency coil. x is the frequency-domain data obtained by performing the Fourier transform on the restored image.

The susceptibility supplement is performed, by the susceptibility estimation network in the current cascade, on the frequency-domain complement data output by the frequency-domain complement network in the previous cascade to obtain the coil susceptibility in the current cascade. If the susceptibility estimation network in the current cascade is not located in the last image processing network, the coil susceptibility in the current cascade is input to an image restoring network of a next image processing network for image-domain information supplement.

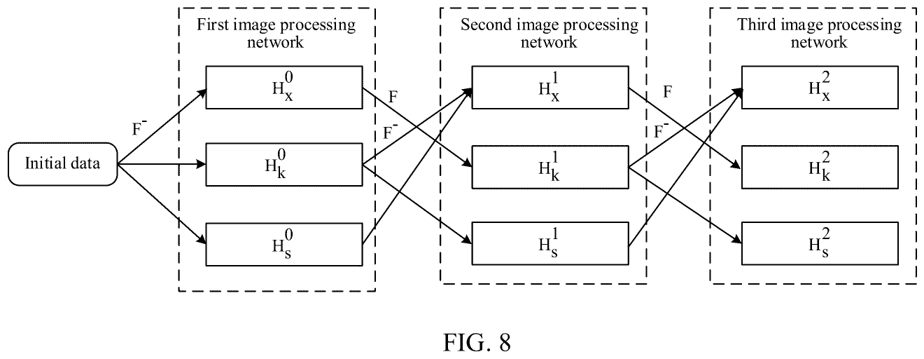

For example, as shown in FIG. 8, the first image processing network includes an image restoring network Hₓ⁰, a frequency-domain complement network Hₖ⁰, and a susceptibility estimation network Hₛ⁰. The second image processing network includes an image restoring network Hₓ¹, a frequency-domain complement network Hₖ¹, and a susceptibility estimation network Hₛ¹. The third image processing network includes an image restoring network Hₓ², a frequency-domain complement network Hₖ², and a susceptibility estimation network Hₛ².

An inverse Fourier transform (F⁻) and a shrinking operation are performed on frequency-domain complement data output by the frequency-domain complement network Hₖ⁰ in the first image processing network to obtain a time-domain image, and the time-domain image is input to the image restoring network Hₓ¹ in the second image processing network. Coil susceptibility output by the susceptibility estimation network Hₛ⁰ in the first image processing network is input to the image restoring network Hₓ¹. The image restoring network Hₓ¹ obtains a restored image in a current cascade based on the input time-domain image and the coil susceptibility. A Fourier transform (F) and an extended operation are performed on the restored image in the current cascade, and the restored image in the current cascade is input to the frequency-domain complement network Hₖ² in the third image processing network. For example, a Fourier transform is performed on the restored image in the current cascade to obtain frequency-domain data corresponding to the restored image in the current cascade, and an extended operation is performed on the frequency-domain data corresponding to the restored image in the current cascade to obtain spectral data after the extended operation.

A Fourier transform (F) and an extended operation are performed on a restored image output by the image restoring network Hₓ⁰ in the first image processing network to obtain corresponding to-be-complemented frequency-domain data. Then, the to-be-complemented frequency-domain data is input to the frequency-domain complement network Hₖ¹ in the second image processing network. The frequency-domain complement network Hₖ² performs frequency-domain information supplement on the to-be-complemented frequency-domain data to obtain frequency-domain complement data in the current cascade. Then, the frequency-domain complement data in the current cascade is input to the susceptibility estimation network Hₛ² in the third image processing network, and an inverse Fourier transform (F⁻) and a shrinking operation are performed on the frequency-domain complement data in the current cascade, then the frequency-domain complement data in the current cascade is input to the image restoring network Hₛ² in the third image processing network.

Susceptibility supplement is performed, by the susceptibility estimation network Hₛ¹ in the second image processing network, on the frequency-domain complement data output by the frequency-domain complement network Hₖ⁰ in the first image processing network to obtain coil susceptibility in a current cascade, and then the coil susceptibility in the current cascade is input to the image restoring network Hₓ² in the third image processing network.

In embodiments of the present disclosure, an information supplement operation is performed respectively on a plurality of pieces of obtained undersampled frequency-domain data by using a plurality of image processing networks that are cascaded to obtain corresponding target restored images, and a target reconstructed image is determined based on the plurality of obtained target restored images. In a process of obtaining the target restored images, an image restoring network, a frequency-domain complement network, and a susceptibility estimation network in the plurality of image processing networks perform cross information supplement in dimensions of an image domain, a frequency domain, and susceptibility information, to obtain more comprehensive image information. In this way, quality of the target reconstructed image is effectively improved when image reconstruction is performed based on the image information.

In some embodiments, a restored image output by an image restoring network in the last image processing network is used as the target restored image. Then, a residual sum of square (RSS) operation is performed on a plurality of target restored images to obtain a target reconstructed image, which is specifically shown in the following Formula (3):

$$\hat{x} = R S S ( {x}_{1} , … , {x}_{N} ) = \sqrt{{Σ}_{i = 1}^{N} \vert {x}_{i} {\vert}^{2}} \qquad ( 3 )$$

N represents a number of the radio frequency coils. xᵢ represents a target restored image corresponding to the i^{th} radio frequency coil.

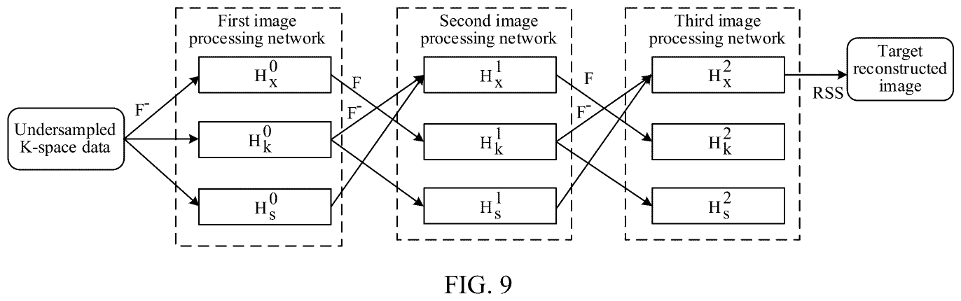

For example, as shown in FIG. 9, the first image processing network includes an image restoring network Hₛ⁰, a frequency-domain complement network Hₖ⁰, and a susceptibility estimation network Hₛ⁰. The second image processing network includes an image restoring network Hₓ¹, a frequency-domain complement network Hₖ¹, and a susceptibility estimation network Hₛ¹. The third image processing network includes an image restoring network Hₓ², a frequency-domain complement network Hₖ², and a susceptibility estimation network Hₛ². The third image processing network is the last image processing network.

An inverse Fourier transform (F⁻) is performed on undersampled K-space data to obtain a time-domain image corresponding to the undersampled K-space data. The time-domain image corresponding to the undersampled K-space data is input to the image restoring network Hₓ⁰. After the image restoring network Hₓ⁰ performs image-domain information supplement, a restored image in a first cascade is output. After a Fourier transform (F) is performed on the restored image in the first cascade to obtain frequency-domain data corresponding to the restored image in the first cascade, and the frequency-domain data corresponding to the restored image in the first cascade is input to the frequency-domain complement network Hₖ¹.

The undersampled K-space data is input to the frequency-domain complement network Hₖ⁰ to obtain frequency-domain complement data in the first cascade. The frequency-domain complement data in the first cascade is input to the susceptibility estimation network Hₛ¹, and an inverse Fourier transform (F⁻) is performed on the frequency-domain complement data in the first cascade to obtain a time-domain image corresponding to the frequency-domain complement data in the first cascade, and the time-domain image corresponding to the frequency-domain complement data in the first cascade is input to the image restoring network Hₓ¹.

Target frequency-domain data lower than a preset frequency is selected from the undersampled K-space data. Then, an inverse Fourier transform (F⁻) is performed on the target frequency-domain data, and the target frequency-domain data is input to the susceptibility estimation network Hₛ⁰ to obtain a time-domain image. The time-domain image is used as coil susceptibility in the first cascade, and the coil susceptibility in the first cascade is input to the image restoring network Hₓ¹.

The image restoring network Hₓ¹ obtains a restored image in a second cascade based on the frequency-domain complement data in the first cascade and the coil susceptibility in the first cascade. A Fourier transform (F) is performed on the restored image in the second cascade to obtain frequency-domain data corresponding to the restored image in the second cascade, and the frequency-domain data corresponding to the restored image in the second cascade is input to the frequency-domain complement network Hₖ².

After the frequency-domain complement network Hₖ¹ performs frequency-domain information supplement on the frequency-domain data corresponding to the restored image in the second cascade, frequency-domain complement data in the second cascade is output. The frequency-domain complement data in the second cascade is input to the susceptibility estimation network Hₛ², and an inverse Fourier transform (F⁻) is performed on the frequency-domain complement data in the second cascade to obtain a time-domain image corresponding to the frequency-domain complement data in the second cascade, and the time-domain image corresponding to the frequency-domain complement data in the second cascade is input to the image restoring network Hₓ².

After the susceptibility estimation network Hₛ¹ performs coil susceptibility supplement, coil susceptibility in the second cascade is output, and the coil susceptibility in the second cascade is input to the image restoring network Hₓ².

The image restoring network Hₓ² outputs a restored image in a third cascade based on the frequency-domain complement data in the second cascade and the coil susceptibility in the second cascade. Then, a residual sum of square operation on a plurality of restored images in a third cascade to obtain a target reconstructed image.

In embodiments of the present disclosure, after target restored images corresponding to a plurality of radio frequency coils are obtained, a residual sum of square operation is performed on the plurality of target restored images to obtain a target reconstructed image, so that image information in the target reconstructed image is distributed more evenly, thereby improving quality of the target reconstructed image.

After obtaining the target reconstructed image by the plurality of image processing networks is described, a joint training process of the plurality of image processing networks is described below, which includes the following operations: performing, based on an undersampled sample data set, joint iteration training on a plurality of to-be-trained processing networks that are cascaded to obtain the plurality of trained image processing networks, the following operations being performed in each iteration training: performing, by the plurality of to-be-trained processing networks, an information supplement operation respectively on a plurality of pieces of sample data selected from the sample data set to obtain a plurality of corresponding prediction restored images and a plurality of pieces of corresponding prediction frequency-domain complement data, and determining a prediction reconstructed image based on the plurality of obtained prediction restored images; and determining a target loss function based on the prediction reconstructed image and the plurality of pieces of obtained prediction frequency-domain complement data, and performing parameter adjustment by using the target loss function.

Specifically, the undersampled sample data is also undersampled K-space data of a human being or an animal. The plurality of pieces of sample data correspond to different radio frequency coils. In an end-to-end manner, a structural similarity (SSIM) loss function and a mean squared error (MSE) loss function are used for training. In a training process, after data in a form of a complex number in K-space and an image domain is divided into a real part and an imaginary part, the data is input to a real part input channel and an imaginary part input channel in the network respectively.

In some embodiments, a first loss function is determined based on the plurality of pieces of prediction frequency-domain complement data and fully-sampled sample data corresponding to the plurality of pieces of sample data, which is specifically shown in the following Formula (4):

$${ℒ}_{k} = {Σ}_{{N}_{k}} ‖ \vert {k}_{n} \vert - \vert {k}_{T} \vert {‖}_{2}^{2} \qquad ( 4 )$$

Nₖ is a number of samples in the sample data set. k_{T} represents prediction frequency-domain complement data output by a to-be-trained processing network in the last cascade. kₙ represents the fully-sampled sample data (fully-sampled K-space data).

A second loss function is determined based on the prediction reconstructed image and a corresponding reference reconstructed image, which is specifically shown in the following Formula (5):

$${ℒ}_{x} = {\sum }_{{N}_{x}} ( 1 - SSIM ( \vert {x}_{n} \vert , \vert {x}_{T} \vert ) ) \qquad ( 5 )$$

Nₓ is a number of sample images obtained by performing an inverse Fourier transform on the sample data in the sample data set. x_{T} represents the prediction reconstructed image. xₙ represents the reference reconstructed image, and the reference reconstructed image is constructed based on the fully-sampled sample data.

The target loss function is determined based on the first loss function and the second loss function, which is specifically shown in the following Formula (6):

$${ℒ}_{s} = {min}_{θ} {ℒ}_{x} + {ℒ}_{k} \qquad ( 6 )$$

θ={θₓ, θₖ, θₛ} and θₓ represent network parameters in an image restoring network. θₓ represents a network parameter in a frequency-domain complement network. θₛ represents a network parameter in a susceptibility estimation network. Lₛ represents the target loss function.

For example, to-be-trained processing networks that are cascaded are set to 10. An image restoring network, a frequency-domain complement network, and a susceptibility estimation network in each to-be-trained processing network are U-net networks. The U-net network includes a compression path (also referred to as a downsampling path) and an extending path (also referred to as an upsampling path). The compression path includes four convolutional modules, and each convolutional module includes a pooling layer. The pooling layer is configured to perform a pooling operation, for example, maximum pooling or average pooling. In some embodiments, previous to the pooling layer, the pooling layer may alternatively include a two-dimensional convolution layer, an activation layer, and a normalization layer that are cascaded in sequence. A negative slope coefficient of the activation layer is 0.2, and a size of a convolution kernel of the two-dimensional convolution layer is 3×3.

A final output result of the compression path is referred to as a compression feature map or a downsampled feature map.

The extending path includes four convolutional modules, and each convolutional module includes an upsampling layer. In some embodiments, previous to the upsampling layer, a two-dimensional convolution layer, an activation layer, and a normalization layer that are cascaded in sequence may alternatively be provided. A negative slope coefficient of the activation layer is 0.2, and a size of a convolution kernel of the two-dimensional convolution layer is 3×3. A number of feature maps starts from 32, 32, and 4 respectively, and the number is doubled after a maximum pooling layer and halved after the upsampling layer. A final output result of the extending path is referred to as an upsampled feature map.

After the real part and the imaginary part are concatenated, the sample data in the form of a complex number in the K-space and the image domain are respectively input to the image restoring network, the frequency-domain complement network, and the susceptibility estimation network through the real part input channel and imaginary part input channel for operation. Then, a target loss value is calculated by using the foregoing Formula (6), and the target loss value is reversely transmitted to the plurality of to-be-trained processing networks that are cascaded. By updating the plurality of to-be-trained processing networks that are cascaded in a manner of minimizing the target loss value, the prediction reconstructed image is increasingly similar to the reference reconstructed image, and data difference between the prediction frequency-domain complement data and the fully-sampled sample data is increasingly small. In addition, to optimize an adjustment process of the network parameters, the network is optimized and trained by using an ADAM algorithm. An initial learning rate is 1.0×10⁻⁴ and decreases with epochs. Each epoch refers to a process of training the to-be-trained processing network once by using all samples.

In embodiments of the present disclosure, an error of a frequency domain is determined based on a plurality of pieces of prediction frequency-domain complement data and fully-sampled sample data corresponding to a plurality of pieces of sample data, and an error of a time domain is determined based on a prediction reconstructed image and a corresponding reference reconstructed image. Then, a target loss function for adjusting a model parameter is obtained by combining the error of the frequency domain and the error of the time-domain. In this way, in a training process, a processing network gradually balances both time-domain prediction and frequency-domain prediction, so as to improve performance of training the obtained processing network.

In some embodiments, to balance generalization of a model to diverse data while ensuring prediction accuracy of the image processing network, regular terms are introduced in a model training process in embodiments of the present disclosure to ensure the image processing network.

Specifically, the frequency-domain complement network is trained by using the following Formula (7):

$${argmin}_{\hat{k}} ‖ k - \hat{k} {‖}_{2}^{2} + {λ}_{k} ‖ x - ℛ ∘ {ℱ}^{- 1} ( \hat{k} ) {‖}_{2}^{2} \qquad ( 7 )$$

k represents the fully-sampled sample data. \hat{k} represents the prediction frequency-domain complement data. x represents the reference reconstructed image. [symbol] represents the shrinking operation. [symbol] ⁻¹ represents the inverse Fourier transform. λₖ∥x− [symbol] ∘ [symbol] ⁻¹(\hat{k})∥₂² represents a regular term in training of the frequency-domain complement network.

The image restoring network is trained by using the following Formula (8):

$${argmin}_{\hat{x}} ‖ x - \hat{x} {‖}_{2}^{2} + {λ}_{x} ‖ \hat{k} - Mℱ ∘ ℰ ( \hat{x} ) {‖}_{2}^{2} \qquad ( 8 )$$

x represents the reference reconstructed image. \hat{x} represents the prediction reconstructed image. M represents a sampling mask. E represents the extended operation. \hat{k} represents the prediction frequency-domain complement data. [symbol] represents the Fourier transform. λₓ∥\hat{k}−M [symbol] ∘ε(\hat{x})∥₂² represents a regular term corresponding to the image restoring network.

The susceptibility estimation network is trained by using the following Formula (9):

$${argmin}_{{θ}_{s}} {λ}_{s} ‖ s - {H}_{s} ( \tilde{s} , {θ}_{s} ) {‖}_{2}^{2} \qquad ( 9 )$$

s represents real coil susceptibility. \tilde{s} represents prediction coil susceptibility. λₛ∥s−Hₛ(\tilde{s},θₛ)∥₂² represents a consistency term corresponding to the susceptibility estimation network.

In embodiments of the present disclosure, regular terms are introduced in a process of joint training of a frequency-domain complement network, an image restoring network, and a susceptibility estimation network, so as to improve generalization of a model to diverse data while ensuring prediction accuracy of a processing network.

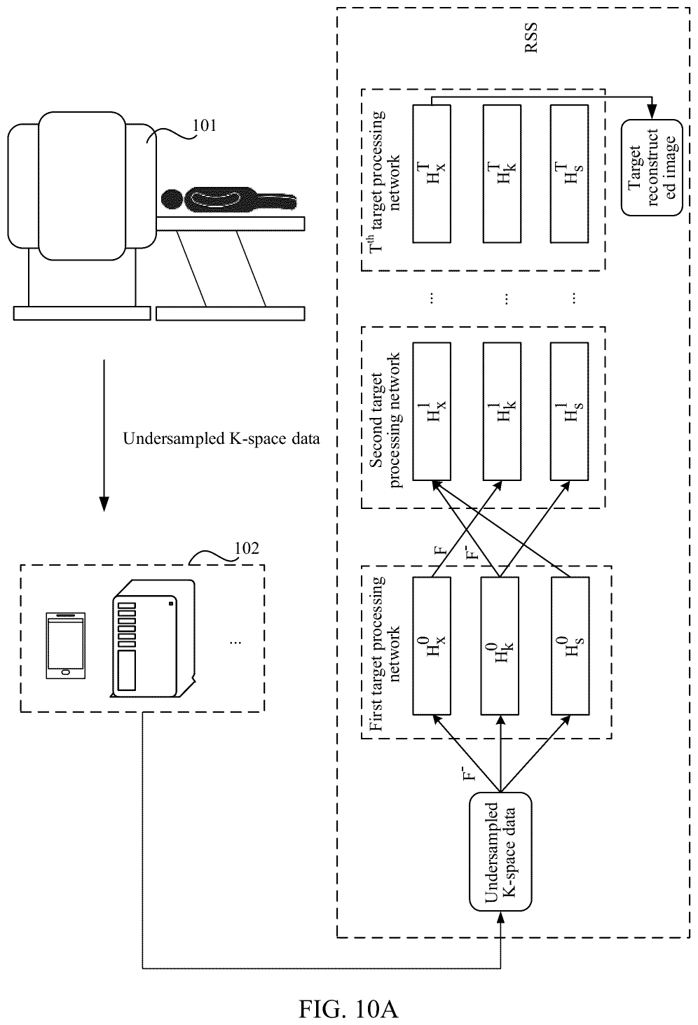

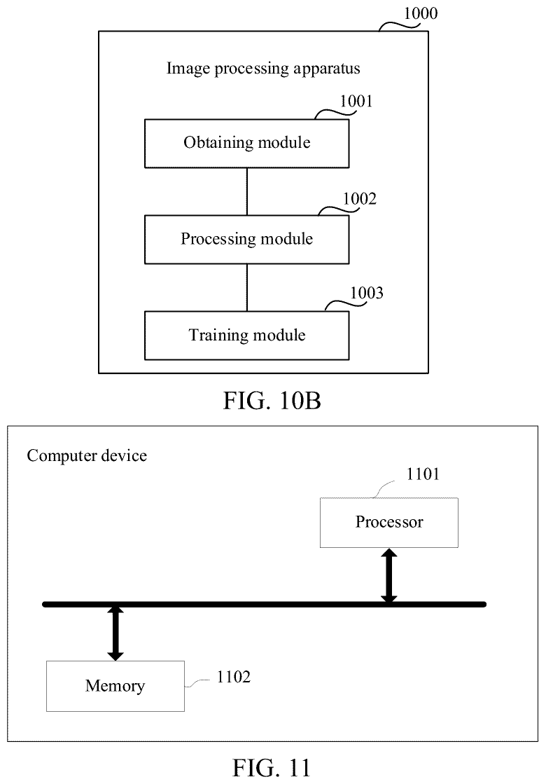

To better describe embodiments of the present disclosure, an image processing method according to an embodiment of the present disclosure is described below in combination with specific implementation scenarios. A process of the method may be performed by the signal collecting device 101 and the image reconstructing device 102 shown in FIG. 1. The signal collecting device 101 includes a nuclear magnetic resonance detecting frame, an examination table, and a plurality of RF coils, as shown in FIG. 10A. The method includes the following operations.

When a patient lies flat on the examination table, the plurality of RF coils are worn on corresponding examination parts of the patient, and then the examination table is controlled to move into an accommodating cavity of the nuclear magnetic resonance detecting frame. Then, each RF coil transmits a RF signal sequence of part of discrete phases to the patient according to a sampling mask, and receives corresponding undersampled K-space data, then sends a plurality of pieces of undersampled K-space data to the image reconstructing device 102. The image reconstructing device 102 includes T+1 image processing networks. The first image processing network includes an image restoring network Hₓ⁰, a frequency-domain complement network Hₖ⁰, and a susceptibility estimation network Hₛ⁰; the second image processing network includes an image restoring network Hₓ¹, a frequency-domain complement network Hₖ¹, and a susceptibility estimation network Hₛ¹; . . . ; and a (T+1) th image processing network includes an image restoring network Hₓ^{T}, a frequency-domain complement network Hₖ^{T}, and a susceptibility estimation network Hₛ^{T}. A T^{th} image processing network is the last image processing network. The image reconstructing device 102 divides the received plurality of pieces of undersampled K-space data into a plurality of groups (slices), and performs the following operations for the undersampled K-space data in each group.

An inverse Fourier transform (F⁻) is performed on the undersampled K-space data to obtain a time-domain image corresponding to the undersampled K-space data. The time-domain image corresponding to the undersampled K-space data is input to the image restoring network Hₓ⁰. After the image restoring network Hₓ⁰ performs image-domain information supplement, a restored image in a first cascade is output. A Fourier transform (F) is performed on the restored image in the first cascade to obtain frequency-domain data corresponding to the restored image in the first cascade, and the frequency-domain data of the restored image in the first cascade is input to the frequency-domain complement network Hₖ¹.

The undersampled K-space data is input to the frequency-domain complement network Hₖ⁰ to obtain frequency-domain complement data in the first cascade. The frequency-domain complement data in the first cascade is input to the susceptibility estimation network Hₛ¹, and an inverse Fourier transform (F⁻) is performed on the frequency-domain complement data in the first cascade to obtain a time-domain image corresponding to the frequency-domain complement data in the first cascade, and the time-domain image corresponding to the frequency-domain complement data in the first cascade is input to the image restoring network Hₓ¹.

Target frequency-domain data lower than a preset frequency is selected from the undersampled K-space data. Then, an inverse Fourier transform (F⁻) is performed on the target frequency-domain data to obtain a time-domain image corresponding to the target frequency-domain data. The time-domain image corresponding to the target frequency-domain data is input to the susceptibility estimation network Hₛ⁰ to obtain coil susceptibility in a first cascade, and the coil susceptibility in the first cascade is input to the image restoring network Hₓ¹.

The image restoring network Hₓ¹ obtains a restored image in a second cascade based on the frequency-domain complement data in the first cascade and the coil susceptibility in the first cascade. A Fourier transform (F) is performed on the restored image in the second cascade to obtain frequency-domain data corresponding to the restored image in the second cascade, and the frequency-domain data corresponding to the restored image in the second cascade is input to the frequency-domain complement network Hₖ².

After the frequency-domain complement network Hₖ¹ performs frequency-domain information supplement, frequency-domain complement data in the second cascade is output. The frequency-domain complement data in the second cascade is input to the susceptibility estimation network Hₛ², and an inverse Fourier transform (F⁻) is performed on the frequency-domain complement data in the second cascade to obtain a time-domain image corresponding to the frequency-domain complement data in the second cascade, and the time-domain image corresponding to the frequency-domain complement data in the second cascade is input to the image restoring network Hₓ².

After the susceptibility estimation network Hₛ¹ performs coil susceptibility supplement, coil susceptibility in the second cascade is output, and the coil susceptibility in the second cascade is input to the image restoring network Hₓ².

By analogy, the image restoring network Hₓ^{T} outputs a restored image in a (T+1)^{th} cascade based on frequency-domain complement data in a T^{th} cascade and coil susceptibility in a T^{th} cascade. Then, a residual sum of square operation is performed on a plurality of restored images in the (T+1)^{th} cascade to obtain two-dimensional anatomic images corresponding to a group (slice).

Two-dimensional anatomic images corresponding to a plurality of groups (slices) are combined to obtain a three-dimensional MRI image corresponding to an examination part. The three-dimensional MRI image may be configured for diagnosis of the examination part of the patient.

In embodiments of the present disclosure, an information supplement operation is performed respectively on a plurality of pieces of obtained undersampled frequency-domain data by using a plurality of image processing networks that are cascaded to obtain corresponding target restored images, and a target reconstructed image is determined based on the plurality of obtained target restored images. In a process of obtaining the target restored images, an image restoring network, a frequency-domain complement network, and a susceptibility estimation network in the plurality of image processing networks perform cross information supplement in dimensions of an image domain, a frequency domain, and susceptibility information, to obtain more comprehensive image information. In this way, quality of the target reconstructed image is effectively improved when image reconstruction is performed based on the more comprehensive image information that is obtained.

Based on the same technical concept, an embodiment of the present disclosure provides an image processing apparatus. As shown in FIG. 10B, the image processing apparatus 1000 includes: an obtaining module 1001, configured to: obtain, by a plurality of radio frequency coils, a plurality of pieces of corresponding undersampled frequency-domain data respectively; and a processing module 1002, configured to: perform, by using a plurality of image processing networks that are cascaded, an information supplement operation respectively on the plurality of pieces of obtained frequency-domain data to obtain a plurality of corresponding target restored images, and determine a target reconstructed image based on the plurality of target restored images, each image processing network including an image restoring network, a frequency-domain complement network, and a susceptibility estimation network.

In the foregoing solution, the obtaining module 1001 is further configured to: perform, for each frequency-domain data, the following operations in sequence according to a cascading order of the plurality of image processing networks: performing, for the first image processing network by an image restoring network in a current cascade, image-domain information supplement on the frequency-domain data, and inputting an obtained restored image in the current cascade to a frequency-domain complement network in a next cascade for frequency-domain information supplement; and performing, by a frequency-domain complement network in the current cascade, frequency-domain information supplement on the frequency-domain data, and inputting obtained frequency-domain complement data in the current cascade to a susceptibility estimation network in the next cascade for susceptibility supplement; and performing, for each non-first image processing network by an image restoring network in a current cascade, image-domain information supplement on frequency-domain complement data output by a frequency-domain complement network in a previous cascade and coil susceptibility output by a susceptibility estimation network in the previous cascade to obtain a restored image in the current cascade, and using the restored image in the current cascade output by an image processing network in the last cascade as the target reconstructed image.

In the foregoing solution, the processing module 1002 is further configured to: perform an inverse Fourier transform on the frequency-domain data to obtain an initial time-domain image; and perform, by the image restoring network in the current cascade, the image-domain information supplement on the initial time-domain image, and input the obtained restored image in the current cascade to the frequency-domain complement network in the next cascade for the frequency-domain information supplement.

In the foregoing solution, the processing module 1002 is further configured to: further perform the following operations for the first image processing network: selecting target data within a preset frequency range from the frequency-domain data, and performing an inverse Fourier transform on the target data to obtain initial coil susceptibility; and performing, by a susceptibility estimation network in the current cascade, susceptibility supplement on the initial coil susceptibility, and inputting obtained coil susceptibility in the current cascade to the frequency-domain complement network in the next cascade for frequency-domain information supplement.

In the foregoing solution, the processing module 1002 is further configured to: perform an inverse Fourier transform and a shrinking operation on the frequency-domain complement data output by the frequency-domain complement network in the previous cascade to obtain a time-domain image; and perform, by the image restoring network in the current cascade, the image-domain information supplement on the time-domain image and the coil susceptibility output by the susceptibility estimation network in the previous cascade to obtain the restored image in the current cascade.

In the foregoing solution, the processing module 1002 is further configured to: further perform the following operations for each non-first image processing network: performing, by a frequency-domain complement network in the current cascade, frequency-domain information supplement on a restored image output by an image restoring network in the previous cascade to obtain frequency-domain complement data in the current cascade; and performing, by a susceptibility estimation network in the current cascade, susceptibility supplement on the frequency-domain complement data output by the frequency-domain complement network in the previous cascade to obtain coil susceptibility in the current cascade.

In the foregoing solution, the processing module 1002 is further configured to: perform a Fourier transform and an extended operation on the restored image output by the image restoring network in the previous cascade to obtain corresponding to-be-complemented frequency-domain data; and perform, by the frequency-domain complement network in the current cascade, the frequency-domain information supplement on the to-be-complemented frequency-domain data to obtain the frequency-domain complement data in the current cascade.

In the foregoing solution, the processing module 1002 is further configured to: perform a residual sum of square operation on the obtained plurality of target restored images to obtain the target reconstructed image.

In the foregoing solution, the image processing apparatus further includes a training module 1003. The training module 1003 is further configured to: perform, based on an undersampled sample data set, joint iteration training on a plurality of to-be-trained processing networks that are cascaded to output the plurality of image processing networks, the following operations being performed in each iteration training: performing, by the plurality of to-be-trained processing networks, an information supplement operation respectively on a plurality of pieces of sample data selected from the sample data set to obtain corresponding prediction restored images and corresponding prediction frequency-domain complement data, and determining a prediction reconstructed image based on the plurality of obtained prediction restored images; and determining a target loss function based on the prediction reconstructed image and the plurality of pieces of obtained prediction frequency-domain complement data, and performing parameter adjustment by using the target loss function.

In the foregoing solution, the training module 1003 is further configured to: determine a first loss function based on the plurality of pieces of prediction frequency-domain complement data and fully-sampled sample data corresponding to the plurality of pieces of sample data; determine a second loss function based on the prediction reconstructed image and a corresponding reference reconstructed image, the reference reconstructed image being constructed based on the fully-sampled sample data; and determine the target loss function based on the first loss function and the second loss function.

In embodiments of the present disclosure, an information supplement operation is performed respectively on a plurality of pieces of obtained undersampled frequency-domain data by using a plurality of image processing networks that are cascaded to obtain corresponding target restored images, and a target reconstructed image is determined based on the plurality of obtained target restored images. In a process of obtaining the target restored images, an image restoring network, a frequency-domain complement network, and a susceptibility estimation network in the plurality of image processing networks perform cross information supplement in dimensions of an image domain, a frequency domain, and susceptibility information, to obtain more comprehensive image information. In this way, quality of the target reconstructed image is effectively improved when image reconstruction is performed based on the more comprehensive image information that is obtained.

Based on the same technical concept, an embodiment of the present disclosure provide a computer device. The computer device may be the image reconstructing device 102 shown in FIG. 1. As shown in FIG. 11, the computer device includes at least one processor 1101 and a memory 1102 connected to the at least one processor. A specific connection medium between the processor 1101 and the memory 1102 is not limited in this embodiment of the present disclosure. In FIG. 11, an example in which the processor 1101 and the memory 1102 are connected through a bus is used. The bus may include an address bus, a data bus, a control bus, and the like.

In this embodiment of the present disclosure, the memory 1102 stores instructions executed by the at least one processor 1101. The at least one processor 1101 may perform operations of the foregoing image processing method by executing the instructions stored in the memory 1102.

The processor 1101 is a control center of the computer device, and is connected to various parts of the computer device by using various interfaces and lines. By running or executing the instructions stored in the memory 1102, the processor invokes data stored in the memory 1102, to perform MRI image reconstruction. In some embodiments, the processor 1101 may include one or more processing units. The processor 1101 may integrate an application processor and a modem processor. The application processor mainly processes an operating system, a user interface, an application program, and the like. The modem processor mainly processes wireless communication. The foregoing modem processor may alternatively not be integrated into the processor 1101. In some embodiments, the processor 1101 and the memory 1102 may be implemented on the same chip. In some embodiments, the processor and the memory may be separately implemented on an independent chip.

The processor 1101 may be a general purpose processor, for example, a central processing unit (CPU), a digital signal processor, an application specific integrated circuit (ASIC), a field programmable gate array, or another programmable logic device, a discrete gate or a transistor logic device, or a discrete hardware component, and may implement or perform the methods, operations, and logical block diagrams disclosed in embodiments of the present disclosure. The general purpose processor may be a microprocessor, any suitable processor, or the like. The operations of the method disclosed with reference to embodiments of the present disclosure may be directly implemented by a hardware processor, or may be implemented by a combination of hardware and software modules in the processor.

As a non-volatile computer-readable storage medium, the memory 1102 may be configured to store non-volatile software programs, non-volatile computer-executable programs, and modules. The memory 1102 may include at least one type of storage medium, for example, a flash memory, a hard disk, a multimedia card, a card-type memory, a random access memory (RAM), a static random access memory (SRAM), a programmable read only memory (PROM), a read only memory (ROM), an electrically erasable programmable read only memory (EEPROM), a magnetic memory, a magnetic disk, and an optical disc. The memory 1102 is any other medium that can be configured to carry or store expected program codes in a form of instructions or data structures and that can be accessed by a computer device, but is not limited thereto. The memory 1102 in this embodiment of the present disclosure may alternatively be a circuit or any other apparatus capable of realizing a storage function, and is configured to store program instructions and/or data.

The term module (and other similar terms such as submodule, unit, subunit, etc.) in the present disclosure may refer to a software module, a hardware module, or a combination thereof. A software module (e.g., computer program) may be developed using a computer programming language. A hardware module may be implemented using processing circuitry and/or memory. Each module can be implemented using one or more processors (or processors and memory). Likewise, a processor (or processors and memory) can be used to implement one or more modules. Moreover, each module can be part of an overall module that includes the functionalities of the module.

An embodiment of the present disclosure provides a computer-readable storage medium, having a computer program stored thereon, the computer program being executable by a computer device, and the program, when run on the computer device, causing the computer device to perform operations of the foregoing image processing method.

An embodiment of the present disclosure provides a computer program product, including a computer program stored on a computer-readable storage medium, the computer program product including program instructions, and the program instructions, when executed by a computer device, causing the computer device to perform operations of the foregoing image processing method.

As disclosed in the present disclosure, an image is reconstructed from frequency-domain data by using a plurality of image processing networks that are cascaded. In a process of obtaining a target restored image, an image restoring network, a frequency-domain complement network, and a susceptibility estimation network in the plurality of image processing networks perform cross information supplement in dimensions of a frequency domain, an image domain, and susceptibility information, to obtain more comprehensive image information. In this way, a reconstructed image has a higher resolution and a higher signal-to-noise ratio, so that quality of a target reconstructed image is effectively improved.

A person skilled in the art may understand that embodiments of the present disclosure may be provided as a method or a computer program product. Therefore, the present disclosure may use a form of hardware-only embodiments, software-only embodiments, or embodiments with a combination of software and hardware. Moreover, the present disclosure may use a form of a computer program product that is implemented on one or more computer-usable storage media (including but not limited to a disk memory, a CD-ROM, an optical memory, and the like) that include computer-usable program code.

The present disclosure is described with reference to flowcharts and/or block diagrams of the method, the device (system), and the computer program product according to embodiments of the present disclosure. Computer program instructions can implement each procedure and/or block in the flowcharts and/or block diagrams and a combination of procedures and/or blocks in the flowcharts and/or block diagrams. These computer program instructions may be provided to a general purpose computer, a special-purpose computer, an embedded processor, or a processor of another programmable data processing device to generate a machine, so that an apparatus configured to implement functions specified in one or more procedures in the flowcharts and/or one or more blocks in the block diagrams is generated by using instructions executed by the computer device or the processor of another programmable data processing device.

These computer program instructions may alternatively be stored in a computer-readable memory that can instruct a computer device or another programmable data processing device to work in a specific manner, so that the instructions stored in the computer-readable memory generate an artifact that includes an instruction apparatus. The instruction apparatus implements a specific function in one or more procedures in the flowcharts and/or in one or more blocks in the block diagrams.

These computer program instructions may alternatively be loaded onto a computer device or another programmable data processing device, so that a series of operations and steps are performed on the computer device or another programmable device, thereby generating computer device-implemented processing. Therefore, the instructions executed on the computer device or another programmable device provide operations for implementing a specific function in one or more processes in the flowcharts and/or in one or more blocks in the block diagrams.

Although exemplary embodiments of the present disclosure have been described, knowing the basic creative concept, a person skilled in the art can make additional changes and modifications to these embodiments. Therefore, the following claims are intended to be construed as to cover the exemplary embodiments and all changes and modifications falling within the scope of the present disclosure.

Clearly, a person skilled in the art can make various modifications and variations to the present disclosure without departing from the spirit and scope of the present disclosure. In this case, if the modifications and variations made to the present disclosure fall within the scope of the claims of the present disclosure and their equivalent technologies, the present disclosure is intended to include these modifications and variations.

What is claimed is:

1. An image processing method, performed by an electronic device, the method comprising:
obtaining, through a plurality of radio frequency coils, a plurality of pieces of undersampled frequency-domain data respectively, a radio frequency coil being configured to obtain one piece of undersampled frequency-domain data;
performing, by using a plurality of image processing networks that are cascaded, an information supplement operation respectively on the plurality of pieces of frequency-domain data to obtain a plurality of corresponding target restored images, a piece of frequency-domain data being configured for obtaining one target restored image, and an image processing network comprising an image restoring network, a frequency-domain complement network, and a susceptibility estimation network; and
determining a target reconstructed image based on the plurality of target restored images.

2. The method according to claim 1, wherein performing the information supplement operation respectively on the plurality of pieces of frequency-domain data to obtain the plurality of corresponding target restored images comprises:
performing, for a piece of frequency-domain data, following operations in sequence according to a cascading order of the plurality of image processing networks:
performing, for the first image processing network by an image restoring network in a current cascade, image-domain information supplement on the frequency-domain data, and inputting an obtained restored image in the current cascade to a frequency-domain complement network in a next cascade for frequency-domain information supplement; and performing, by a frequency-domain complement network in the current cascade, frequency-domain information supplement on the frequency-domain data, and inputting obtained frequency-domain complement data in the current cascade to a susceptibility estimation network in the next cascade for susceptibility supplement; and
performing, for a non-first image processing network by an image restoring network in a current cascade, image-domain information supplement on frequency-domain complement data output by a frequency-domain complement network in a previous cascade and coil susceptibility output by a susceptibility estimation network in the previous cascade to obtain a restored image in the current cascade, and using the restored image in the current cascade output by an image processing network in the last cascade as the target reconstructed image.

3. The method according to claim 2, wherein performing, by the image restoring network in the current cascade, the image-domain information supplement on the frequency-domain data, and inputting the obtained restored image in the current cascade to the frequency-domain complement network in the next cascade for frequency-domain information supplement comprises:
performing an inverse Fourier transform on the frequency-domain data to obtain an initial time-domain image; and
performing, by the image restoring network in the current cascade, the image-domain information supplement on the initial time-domain image, and inputting the obtained restored image in the current cascade to the frequency-domain complement network in the next cascade for the frequency-domain information supplement.

4. The method according to claim 3, wherein performing, by the image restoring network in the current cascade, the image-domain information supplement on the initial time-domain image comprises:
performing, by the image restoring network in the current cascade, following processing on the initial time-domain image:
performing a pooling operation on the initial time-domain image to obtain a pooled feature map; and
performing upsampling on a downsampled feature map to obtain an upsampled feature map, and using the upsampling feature map as the obtained restored image in the current cascade.

5. The method according to claim 2, further comprising:
performing following operations for the first image processing network:
selecting target data within a preset frequency range from the frequency-domain data, and performing an inverse Fourier transform on the target data to obtain initial coil susceptibility; and
performing, by a susceptibility estimation network in the current cascade, susceptibility supplement on the initial coil susceptibility, and inputting obtained coil susceptibility in the current cascade to the frequency-domain complement network in the next cascade for frequency-domain information supplement.

6. The method according to claim 2, wherein performing, by the image restoring network in the current cascade, image-domain information supplement on frequency-domain complement data output by the frequency-domain complement network in the previous cascade and the coil susceptibility output by the susceptibility estimation network in the previous cascade to obtain the restored image in the current cascade comprises:
performing an inverse Fourier transform and a shrinking operation on the frequency-domain complement data output by the frequency-domain complement network in the previous cascade to obtain a time-domain image; and
performing, by the image restoring network in the current cascade, the image-domain information supplement on the time-domain image and the coil susceptibility output by the susceptibility estimation network in the previous cascade to obtain the restored image in the current cascade.

7. The method according to claim 2, further comprising:
performing following operations for the non-first image processing network:
performing, by a frequency-domain complement network in the current cascade, frequency-domain information supplement on a restored image output by an image restoring network in the previous cascade to obtain frequency-domain complement data in the current cascade; and
performing, by a susceptibility estimation network in the current cascade, susceptibility supplement on the frequency-domain complement data output by the frequency-domain complement network in the previous cascade to obtain coil susceptibility in the current cascade.

8. The method according to claim 7, wherein performing, by the frequency-domain complement network in the current cascade, the frequency-domain information supplement on a restored image output by the image restoring network in the previous cascade to obtain frequency-domain complement data in the current cascade comprises:
performing a Fourier transform and an extended operation on the restored image output by the image restoring network in the previous cascade to obtain corresponding to-be-complemented frequency-domain data; and
performing, by the frequency-domain complement network in the current cascade, the frequency-domain information supplement on the to-be-complemented frequency-domain data to obtain the frequency-domain complement data in the current cascade.

9. The method according to claim 1, wherein determining the target reconstructed image based on the plurality of target restored images comprises:
performing a residual sum of square operation on the obtained plurality of target restored images to obtain the target reconstructed image.

10. The method according to claim 1, further comprising:
performing joint training by using the following manners to obtain the plurality of image processing networks:
performing, based on an undersampled sample data set, joint iteration training on a plurality of to-be-trained processing networks that are cascaded to obtain the plurality of image processing networks, the following operations being performed in each iteration training:
performing, by the plurality of to-be-trained processing networks, an information supplement operation respectively on a plurality of pieces of sample data selected from the sample data set to obtain a plurality of corresponding prediction restored images and a plurality of pieces of corresponding prediction frequency-domain complement data, and determining a prediction reconstructed image based on the plurality of prediction restored images; and
determining a target loss function based on the prediction reconstructed image and the plurality of pieces of prediction frequency-domain complement data, and performing parameter adjustment by using the target loss function.

11. The method according to claim 10, wherein determining the target loss function based on the prediction reconstructed image and the plurality of pieces of prediction frequency-domain complement data comprises:
determining a first loss function based on the plurality of pieces of prediction frequency-domain complement data and fully-sampled sample data corresponding to the plurality of pieces of sample data;
determining a second loss function based on the prediction reconstructed image and a corresponding reference reconstructed image, the reference reconstructed image being constructed based on the fully-sampled sample data; and
determining the target loss function based on the first loss function and the second loss function.

12. A computer device, comprising a memory, at least one processor, and a computer program stored in the memory and executable on the at least one processor for performing:
obtaining, through a plurality of radio frequency coils, a plurality of pieces of undersampled frequency-domain data respectively, a radio frequency coil being configured to obtain one piece of undersampled frequency-domain data;
performing, by using a plurality of image processing networks that are cascaded, an information supplement operation respectively on the plurality of pieces of frequency-domain data to obtain a plurality of corresponding target restored images, a piece of frequency-domain data being configured for obtaining one target restored image, and an image processing network comprising an image restoring network, a frequency-domain complement network, and a susceptibility estimation network; and
determining a target reconstructed image based on the plurality of target restored images.

13. The device according to claim 12, wherein the at least one processor is further configured to perform:
performing, for a piece of frequency-domain data, following operations in sequence according to a cascading order of the plurality of image processing networks:
performing, for the first image processing network by an image restoring network in a current cascade, image-domain information supplement on the frequency-domain data, and inputting an obtained restored image in the current cascade to a frequency-domain complement network in a next cascade for frequency-domain information supplement; and performing, by a frequency-domain complement network in the current cascade, frequency-domain information supplement on the frequency-domain data, and inputting obtained frequency-domain complement data in the current cascade to a susceptibility estimation network in the next cascade for susceptibility supplement; and
performing, for a non-first image processing network by an image restoring network in a current cascade, image-domain information supplement on frequency-domain complement data output by a frequency-domain complement network in a previous cascade and coil susceptibility output by a susceptibility estimation network in the previous cascade to obtain a restored image in the current cascade, and using the restored image in the current cascade output by an image processing network in the last cascade as the target reconstructed image.

14. The device according to claim 13, wherein the at least one processor is further configured to perform:
performing an inverse Fourier transform on the frequency-domain data to obtain an initial time-domain image; and
performing, by the image restoring network in the current cascade, the image-domain information supplement on the initial time-domain image, and inputting the obtained restored image in the current cascade to the frequency-domain complement network in the next cascade for the frequency-domain information supplement.

15. The device according to claim 14, wherein the at least one processor is further configured to perform:
performing, by the image restoring network in the current cascade, following processing on the initial time-domain image:
performing a pooling operation on the initial time-domain image to obtain a pooled feature map; and
performing upsampling on a downsampled feature map to obtain an upsampled feature map, and using the upsampling feature map as the obtained restored image in the current cascade.

16. The device according to claim 13, wherein the at least one processor is further configured to perform:
performing following operations for the first image processing network:
selecting target data within a preset frequency range from the frequency-domain data, and performing an inverse Fourier transform on the target data to obtain initial coil susceptibility; and
performing, by a susceptibility estimation network in the current cascade, susceptibility supplement on the initial coil susceptibility, and inputting obtained coil susceptibility in the current cascade to the frequency-domain complement network in the next cascade for frequency-domain information supplement.

17. The device according to claim 13, wherein the at least one processor is further configured to perform:
performing an inverse Fourier transform and a shrinking operation on the frequency-domain complement data output by the frequency-domain complement network in the previous cascade to obtain a time-domain image; and
performing, by the image restoring network in the current cascade, the image-domain information supplement on the time-domain image and the coil susceptibility output by the susceptibility estimation network in the previous cascade to obtain the restored image in the current cascade.

18. The device according to claim 13, wherein the at least one processor is further configured to perform:
performing following operations for the non-first image processing network:
performing, by a frequency-domain complement network in the current cascade, frequency-domain information supplement on a restored image output by an image restoring network in the previous cascade to obtain frequency-domain complement data in the current cascade; and
performing, by a susceptibility estimation network in the current cascade, susceptibility supplement on the frequency-domain complement data output by the frequency-domain complement network in the previous cascade to obtain coil susceptibility in the current cascade.

19. The method according to claim 18, wherein the at least one processor is further configured to perform:
performing a Fourier transform and an extended operation on the restored image output by the image restoring network in the previous cascade to obtain corresponding to-be-complemented frequency-domain data; and
performing, by the frequency-domain complement network in the current cascade, the frequency-domain information supplement on the to-be-complemented frequency-domain data to obtain the frequency-domain complement data in the current cascade.

20. A non-transitory computer-readable storage medium, containing a computer program that, when being executed, causes a computer device to perform:
obtaining, through a plurality of radio frequency coils, a plurality of pieces of undersampled frequency-domain data respectively, a radio frequency coil being configured to obtain one piece of undersampled frequency-domain data;
performing, by using a plurality of image processing networks that are cascaded, an information supplement operation respectively on the plurality of pieces of frequency-domain data to obtain a plurality of corresponding target restored images, a piece of frequency-domain data being configured for obtaining one target restored image, and an image processing network comprising an image restoring network, a frequency-domain complement network, and a susceptibility estimation network; and
determining a target reconstructed image based on the plurality of target restored images.
